(19) United States
(12) Patent Application Publication
(10) Pub. No.: US 2025/0128618 A1
(43) Pub. Date: Apr. 24, 2025

(54) ELECTRICAL CONNECTOR SYSTEM AND ELECTRIC VEHICLE

(71) Applicant: TE Connectivity India Private Limited, Bangalore (IN)

(72) Inventors: Akshay Sanjay PATIL, Bangalore (IN); Abhishek KRISHNA, Bangalore (IN); Kashyap PRAKASH B, Bangalore (IN); Danappa HUGAR, Bangalore (IN)

(21) Appl. No.: 18/922,615

(22) Filed: Oct. 22, 2024

(30) Foreign Application Priority Data
Oct. 23, 2023 (IN) 202341072257

(51) Int. Cl. B60L 53/16; H01R 13/04; H01R 13/424; H01R 13/512; H05K 7/20

(52) U.S. Cl. CPC B60L 53/16; H01R 13/04; H01R 13/424; H01R 13/512; H05K 7/20127; H05K 7/20254; H05K 7/20272; H05K 7/20409; H05K 7/20854; H05K 7/20872; H01R 2201/26

(57) ABSTRACT

An electrical connector system includes an electrical connector, a cooling module and fixing means. The electrical connector includes a first terminal, a second terminal, and a mounting assembly to which the first and second terminals are fixed. In an assembled state, the cooling module can transfer heat from the electrical connector to a liquid, and includes a passage for conveying the liquid and one or more thermally conductive bodies for conducting heat from the first and second terminals to the passage. The fixing means is for fixing the cooling module to the electrical connector in the assembled state. In a disassembled state, the cooling module is physically independent of the electrical connector. The electrical connector system can be brought from the disassembled state to the assembled state while the first and second terminals remain fixed to the mounting assembly, and/or the electrical connector system can be brought from the assembled state to the disassembled state while the first and second terminals remain fixed to the mounting assembly.

### CROSS REFERENCE TO RELATED APPLICATIONS

This application claims the benefit of IN application Ser. No. 20/234,1072257, filed 23 Oct. 2023, the subject matter of which is herein incorporated by reference in its entirety.

### BACKGROUND OF THE INVENTION

The application relates to an electrical connector system that includes an electrical connector and a cooling module, and to an electric vehicle with the electrical connector system.

When a current flows through an electrical connector, resistance to the current generates heat. This heat builds up in the electrical connector, causing the electrical connector's temperature to increase, which allows the heat to diffuse into the environment. In some circumstances, the build up of heat and resulting increase in temperature can damage the electrical connector and its surroundings. To avoid this, electrical connectors may be configured with heat management means for conducting or convecting heat away from the electrical connector.

A need for heat management means may depend on the conditions under which an electrical connector is used. These conditions can change. For example, the electrical connector may be required to operate at higher currents in order to reduce a battery charge time, or for longer periods of time in order to charge a larger battery, or in higher ambient temperatures as a result of movement to a different operating environment. In these cases, an electrical connector may have to be replaced or modified to add heat management means. Similarly, a change in conditions may remove a need for a heat management means, rendering the heat management means an unnecessary mass and maintenance burden. In these cases, the electrical connector may be replaced or modified to remove the heat management means. Even if conditions do not change, the heat management means may fail or require maintenance, for which the electrical connector may have to be replaced or disassembled.

There is a need for an electrical connector system having improved thermal management.

### BRIEF DESCRIPTION OF THE INVENTION

In an embodiment, an electrical connector system is provided including an electrical connector, a cooling module and fixing means. The electrical connector includes a first terminal, a second terminal, and a mounting assembly to which the first and second terminals are fixed. In an assembled state, the cooling module can be used to transfer heat from the electrical connector to a liquid, and includes a passage for conveying the liquid and one or more thermally conductive bodies for conducting heat from the first and second terminals to the passage. The fixing means is for fixing the cooling module to the electrical connector in the assembled state. In a disassembled state, the cooling module is physically independent of the electrical connector. The electrical connector system can be brought from the disassembled state to the assembled state while the first and second terminals remain fixed to the mounting assembly, and/or the electrical connector system can be brought from the assembled state to the disassembled state while the first and second terminals remain fixed to the mounting assembly.

In the assembled state, heat can be transferred from the electrical connector to the liquid by conducting heat from the first and second terminals, through the one or more thermally conductive bodies, to the passage. This allows the amount of heat that is dissipated from the electrical connector to be increased by increasing a flow of the liquid through the passage and/or by decreasing a temperature of the liquid. In the disassembled state, the electrical connector and the cooling module can be separated. This makes it possible for the electrical connector to be used without the cooling module, in case the increased heat dissipation provided by the cooling module is unnecessary or the cooling module requires removal for maintenance or replacement. The electrical connector system can be brought from the disassembled state to the assembled state without unfixing the first and second terminals from the mounting assembly. Therefore, the electrical connector system can obtain the increased heat dissipation in the assembled state without interfering with the primary structure of the electrical connector. Additionally, or alternatively, the electrical connector can be brought from the assembled state to the disassembled state without unfixing the first and second terminals from the mounting assembly. Therefore, the electrical connector system allows the cooling module to be removed for maintenance or weight reduction without interfering with the primary structure of the electrical connector. Thus, the utility of the electrical connector system is increased.

The above solution may be further improved by adding one or more of the following optional features. Each of the following optional features is advantageous on its own and may be combined independently with any other optional feature.

Preferably, the one or more thermally conductive bodies have one or more convective heat transfer surfaces that define at least a portion of the passage, and, in the assembled state, at least a portion of the one or more convective heat transfer surfaces is interposed between the first and second terminals.

By locating at least the portion of the one or more convective heat transfer surfaces between the first and second terminals, the space that is provided between the first and second terminals for electrical isolation and structural reasons can be utilised for an additional function of transferring heat to the liquid. Thus, the electrical connector system can provide increased heat dissipation in a more compact structure.

Preferably, in the assembled state, a first surface of the one or more thermally conductive bodies is substantially parallel to and facing a primary heat transmitting surface of the first terminal and a second surface of the one or more thermally conductive bodies is substantially parallel to and facing a primary heat transmitting surface of the second terminal.

By making the first and second surfaces parallel and facing the primary heat transmitting surfaces, the one or more thermally conductive bodies can be brought close to or in contact with the first and second terminals in the assembled state. This makes it possible to reduce thermal resistance between the first and second terminals and the thermally conductive bodies, and suppress or obviate a requirement for a thermal interface body or a thermal interface material between the first and second surfaces parallel and facing the primary heat transmitting surfaces. A thermal resistance between the first and second terminals and the passage can therefore be made small, so that the heat dissipation from the electrical connector is increased. Thus, the performance of the electrical connector system can be increased.

More preferably, the primary heat transmitting surfaces of the first and second terminals are substantially flat.

By making the primary heat transmitting surfaces substantially flat, the first and second surfaces can be brought close to the primary heat transmitting surfaces more easily and reliably. Thus, the performance of the electrical connector system can be more reliably ensured.

Still more preferably, the primary heat transmitting surfaces of the first and second terminals face one another and are substantially parallel.

With the primary heat transmitting surfaces opposed and parallel, the cooling module can be inserted between the first and second terminals to bring the first and second surfaces close to the primary surfaces, from a direction parallel to the planes of the primary heat transmitting surfaces. This simplifies bringing the electrical connector system from the disassembled state to the assembled state, and/or from the assembled state to the disassembled state. It also allows the cooling module to make use of the space between the first and second terminals that is provided for electrical isolation and structural reasons. Thus, the ease in maintaining and/or modifying the electrical connector system is increased while the increased heat dissipation can be obtained in a more compact structure.

Still more preferably, each of the first and second terminals has a secondary heat transmitting surface that is parallel to and faces a direction opposite to the respective primary heat transmitting surface, the one or more thermally conductive bodies include a first air cooled portion with a plurality of fins and a second air cooled portion with a plurality of fins, and in the assembled state, a surface of the first air-cooled portion is substantially parallel to and facing the secondary heat transmitting surface of the first terminal, and a surface of the second air-cooled portion is substantially parallel to and facing the secondary heat transmitting surface of the second terminal.

The first and second air-cooled portions enable increased heat dissipation from the electrical connector through convection into the surrounding air. Specifically, in the assembled state, heat can be transferred from the secondary heat transmitting surfaces, through the one or more thermally conductive bodies to the fins, where it is transferred into the surrounding air. The increased surface area between the one or more thermally conductive bodies and the air that is provided by the fins reduces the thermal resistance between the first and second terminals and the surrounding air in the assembled state, so that the amount of heat that can be dissipated from the electrical connector is increased. Thus, the performance of the electrical connector system is increased.

Preferably, the mounting assembly comprises a main body and secondary locking body that is fixed to the main body, and each of the first and second terminals has a protruding portion that is clamped between the main body and the secondary body.

The use of the main body and the secondary locking body to fix the first and second terminals to the mounting assembly allows the strength and rigidity of the electrical connector to be ensured in a simple structure that can easily keep the first and second terminals fixed to the mounting assembly when bringing the electrical connector system from the disassembled state to the assembled state, and/or from the assembled state to the disassembled state. Thus, the utility of the electrical connector can be ensured with a simple structure.

Preferably, the cooling module has a first opening and a second opening and is configured to simultaneously receive a connection portion of the first terminal through the first opening and a connection portion of the second terminal through the second opening when the electrical connector system is brought from the disassembled state to the assembled state.

By providing the cooling module with openings for receiving portions of the first and second terminals when bringing the electrical connector system from the disassembled state to the assembled state, and/or from the assembled state to the disassembled state, appropriate positioning of the cooling module with respect to the electrical connector in the assembled state can be more easily and reliably ensured. Thus, the performance and utility of the electrical connector system can be more reliably attained.

Preferably, each of the first and second terminals comprises a connection portion for connection to a cable, wherein each connection portion has a hole for receiving a bolt of a cable connector.

By providing means for connecting the terminals to cables via bolts, a connection to the cables can be made easily separable, so that bringing the electrical connector system from the disassembled state to the assembled state, and/or from the assembled state to the disassembled state, can be made easier. Thus, the utility of the electrical connector system can be improved.

Preferably, the cooling module includes one or more thin thermal interface bodies that are electrically insulative and fixed to at least a portion of the one or more thermally conductive bodies. In the assembled state, the one or more thin thermal interface bodies are interposed between the one or more thermally conductive bodies and at least one of the first and second terminals, and contact the at least one of the first and second terminals.

The thin thermal interface bodies can reduce thermal resistance between the one or more thermally conductive bodies and the at least one of the first and second terminals in the assembled state, whilst also electrically isolating the cooling module from the at least one of the first and second terminals. This allows the performance of the electrical connector to be ensured in with a simple structure. By providing the thin thermal interface body as a body that is fixed to the thermally conductive body, it becomes possible to replace the thin thermal interface body with less interference with the cooling module structure. Accordingly, a useful life of the cooling module can be increased despite wear to the thin thermal interface body after repeatedly being brought to and from the assembled state. Thus, the performance and utility of the electrical connector system can be ensured over the useful life with less materials.

Preferably, the one or more thin thermal interface bodies are of an elastometric material, preferably a silicone based material.

The elastometric material allows the thin thermal interface bodies to easily conform to a gap between the one or more thermally conductive bodies and the at least one of the first and second terminals. This reduces an impact of dimensional variations on the thermal resistance between the one or more thermally conductive bodies and the at least one of the first and second terminals. Thus, the performance of the electrical connector system can be more reliably ensured.

Preferably, the mounting assembly has one or more threaded holes, the fixing means includes a base plate that has one or more holes and is configured to fit the cooling module, and the fixing means is configured to be fixed to the mounting assembly in the assembled state by one or more screws, each of the one or more screws penetrating one of the one or more holes and threading into one of the one or more threaded holes.

By providing the base plate for fitting the cooling module, and configuring the base plate to be fixed to the mounting assembly in the assembled state, the cooling module can be reliably located with respect to the electrical connector in the assembled state. By reliably locating the cooling module with respect to the electrical connector in the assembled state, the thermal resistance between the first and second terminals and the thermally conductive bodies can more be reliably attained. Thus, the performance of the electrical connector system can be more reliably ensured.

Preferably, the fixing means includes a base plate and a cover plate, and is configured to fix the cooling module in the assembled state with a physical interlock between the base plate and the cover plate, the physical interlock being configured to be released by elastic deformation of the base plate and/or the cover plate.

By providing the physical interlock between the cooling module and the mounting assembly, the cooling module can be fixed to the mounting assembly without, or with fewer, additional parts. Thus, the electrical connector assembly can be simplified.

Preferably, the one or more thermally conductive bodies are of a thermally conductive ceramic, preferably aluminum oxide, aluminum nitride or beryllium oxide.

By using a thermally conductive ceramic for the thermally conductive bodies, electrical conductivity in the cooling module can be reduced, so that electrical isolation between the first and second terminals can be more easily ensured. Thus, the performance of the electrical connector system can be more reliably ensured.

Preferably, the electrical connector system is part of a vehicle, the vehicle further comprising an electric motor for propelling the vehicle, a coolant circuit configured to circulate a coolant liquid through the passage, and a battery for supplying electric power to the electric motor. In this case, the electrical connector system is in the assembled state, is fixed to the vehicle via the mounting assembly, and is connected to the battery such that electric power applied to the first and second terminals can charge the battery.

By providing the electrical connector system in the vehicle, the cooling module can use the coolant circuit of the vehicle as a source of the liquid. The ability to bring the electrical connector system from the assembled state to the disassembled state without unfixing the first and second terminals from the mounting assembly also makes it easier to inspect, service, replace and remove the cooling module. Thus, the maintainability and utility of the vehicle is increased.

### BRIEF DESCRIPTION OF THE DRAWINGS

Further features and advantages of the invention will become apparent from the following description of preferred embodiments of the invention, given by way of example only, which is made with reference to the accompanying drawings, in which:

FIG. 1 is a front perspective view of a connector system according to a first embodiment in an assembled state;

FIG. 2 is a front view of the connector system from FIG. 1;

FIG. 3 is an exploded perspective view of an electrical connector that is part of the connector system from FIG. 1;

FIG. 4 is a rear perspective view of the connector system from FIG. 1 in a disassembled state;

FIG. 5 is a rear perspective view of the connector system from FIG. 1, in the assembled state;

FIG. 6 is a side view of the connector system from FIG. 1 in the assembled state;

FIG. 7 is a cross-sectional view of the connector system at A-A from FIG. 6 in the assembled state;

FIG. 8 is a perspective view of the connector system according to a second embodiment in an assembled state;

FIG. 9 is a side view of the connector system from FIG. 9 in the assembled state;

FIG. 10 is a detail cross-sectional view of the connector system at B-B from FIG. 9, in the assembled state, with the main body omitted for clarity; and

FIG. 11 is a schematic view of a vehicle according to a third embodiment.

### DETAILED DESCRIPTION OF THE INVENTION

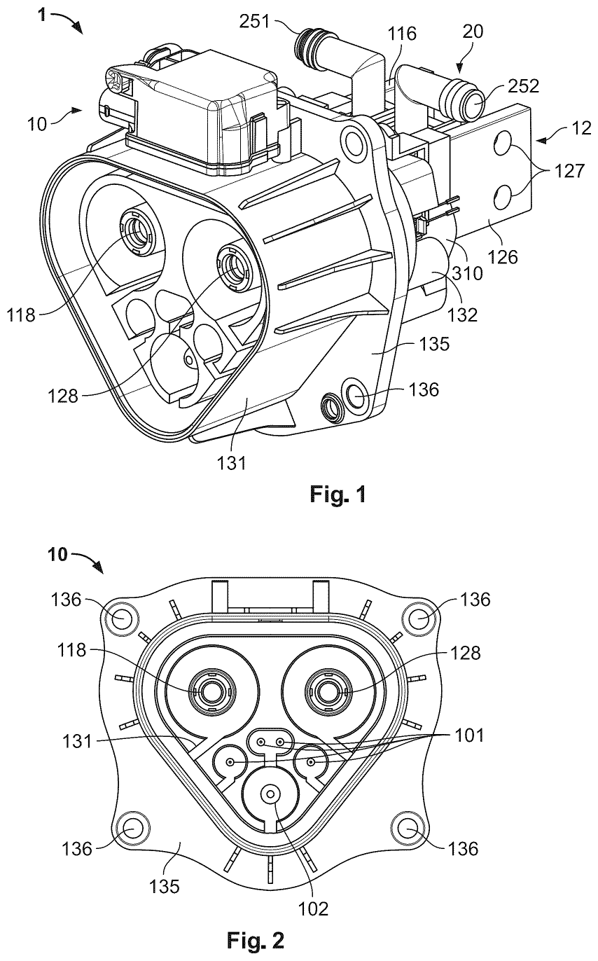

FIG. 1 illustrates an electrical connector system 1 in a front perspective view in an assembled state in accordance with an exemplary embodiment. The electrical connector system 1 includes an electrical connector 10, a cooling module 20 and fixing means 30.

The electrical connector 10 is suitable for use as a charging inlet for an electric vehicle 5, where the electrical connector 10 receives a charging plug (not shown) that supplies power through the electrical connector 10 to charge a battery 3 of the electric vehicle 5. In particular, the electrical connector 10 is suitable for use in a Megawatt Charging System (MCS).

The electrical connector 10 includes a mounting assembly 13 that has a main body 131 and a secondary locking body 132. Pins 101, 102, 118, 128 are exposed on a front side of the main body 131, and the main body 131 is configured to receive the charging plug from the front side so that terminals (not shown) in the charging plug can be brought into contact with the pins 101, 102, 118, 128. As shown in FIG. 2, the pins include four signalling/detection pins 101, a protective earth pin 102 and two DC pins 118, 128 through which the power is primarily transferred.

The main body 131 also includes a mounting flange 135 with mounting holes 136 for securing the electrical connector 10 to a structure (not shown) of the vehicle 5. The main body 131 and the secondary locking body 132 are made from an electrically isolating material such as a thermoplastic.

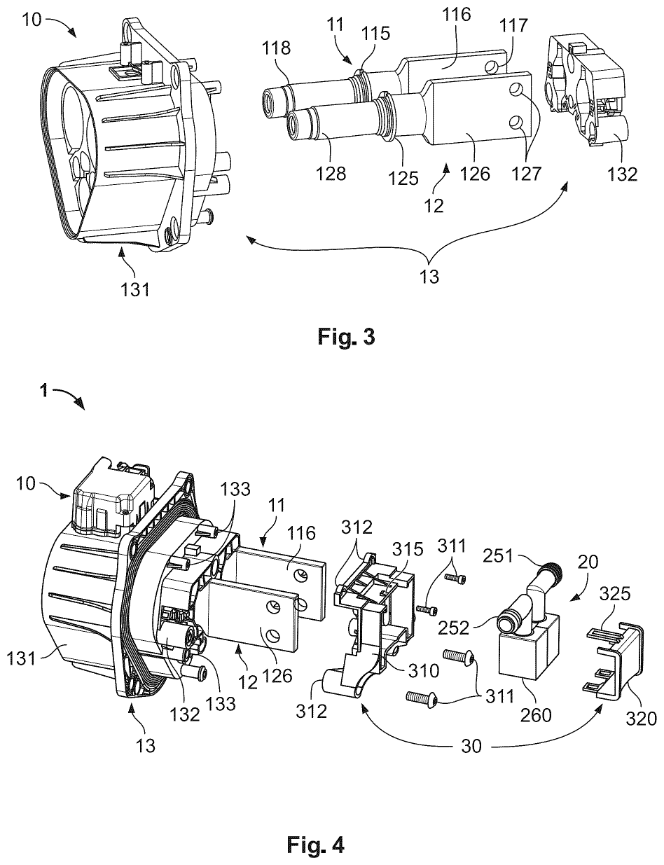

As shown in the exploded view of the electrical connector 10 in FIG. 3, the DC pins 118, 128 are contact portions 118, 128 of first and second terminals 11, 12 that extend rearwards. The first and second terminals 11, 12 are made from a material with high electrical conductivity, such as copper or copper alloy. The secondary locking body 132 is attached to the rear side of the main body 131. Each of the first and second terminals 11, 12 is provided with a protruding portion 115, 125 in the form of a flange approximately mid-way along its length. These protruding portions 115, 125 are retained between the main body 131 and the secondary locking body 132, thereby fixing the first and second terminals 11, 12 in the front-rear direction. The first and second terminals 11, 12 have circular cross sections that become rectangular toward the rear where they include connection portions 116, 126. The first and second terminals are electrically isolated from one another and serve to conduct opposing direct currents (DC) from the contact portions 118, 128 at the front to the connection portions 116, 126 at the rear.

FIG. 4 is a perspective view of the electrical connector system 1 in a disassembled state. The rectangular cross section of the first and second terminals 11, 12 extends back from the rear of the secondary locking body 132, the rectangular cross section being oriented so that the shorter dimension is parallel to the direction in which the first and second terminals 11, 12 are spaced apart from each other. The ends of the first and second terminals 11, 12 are the connection portions 116, 126. The connection portions 116, 126 each have one or more holes 117, 127 for receiving bolts for clamping cables to the connection portions 116, 126. In place of the connection portions 116, 126 with the holes 117, 127, the first and second terminals 11, 12 may be provided with other means suitable for connection with cables, such as a cable connector or welding tabs.

The cooling module 20 is provided as heat management means for transferring heat away from the electrical connector 10. As shown in FIG. 4, a main portion of the cooling module 20 has a substantially cuboid shape. The cooling module 20 has an inlet 251 for receiving a coolant liquid and an outlet 252 for discharging the coolant liquid. A thin thermal interface body 260 is folded around the cooling module 20 to substantially cover the cuboid shaped main portion. The thin thermal interface body 260 is of an electrically isolating material that has high thermal conductivity, such as a thermally conductive silicone. Various means for supplying the cooling liquid to the inlet 251 and for accepting the cooling liquid discharged from the outlet 252 can be used and are not shown in this embodiment.

The fixing means 30 is provided for fixing the cooling module 20 to the electrical connector 10. The fixing means 30 may include a housing configured to hold the cooling module 20. The fixing means 30 may include a latch or clip for holding the cooling module 20. The fixing means may include a band for holding the cooling module 20. The fixing means 30 may use fasteners, latches, clips, bands, adhesive, heat stakes, compression fittings, or other securing elements to hold the cooling module 20 to the electrical connector 10. As shown in FIG. 4, the fixing means 30 includes a base plate 310, four screws 311, and a cover plate 320. The main body 131 is provided with four threaded holes and the base plate 310 is provided with four holes 312. The base plate 310 can be fixed to the main body 131 by screwing the four screws 311 through the corresponding holes 312 in the base plate 310 into the threaded holes 133 in the main body. The cover plate 320 has clips 325 that engage with hooks 315 on the base plate 310. The clips 325 and the hooks 315 constitute a physical interlock that can be released by elastic deformation of the cover plate 320. The physical interlock can be modified to provide the clips 325 on the base plate 310 and the hooks 315 on the cover plate 320.

The electrical connector system 1 is shown in a disassembled state in FIG. 4. In the disassembled state, both of the terminals 11, 12 are fixed to the mounting assembly 13 via the main body 131 and the secondary locking body 132. At the same time, the cooling module 20 is physically independent of the electrical connector 10.

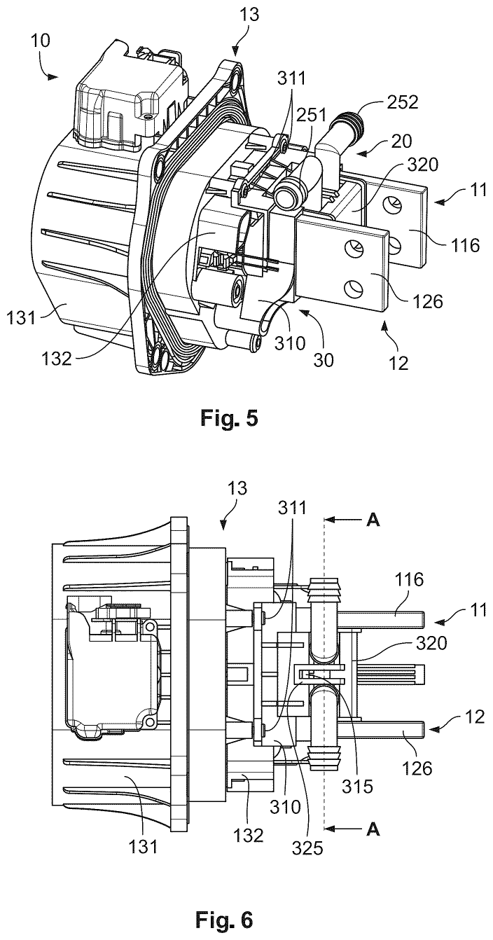

The electrical connector system 1 is shown in an assembled state in FIGS. 1 and 5 to 7. In the assembled state, a thermally conductive body 21 in the cooling module 20 is thermally coupled to the first and second terminals 11, 12. The fixing means 30 fixes the cooling module 20 to the electrical connector 10 in the assembled state. The thermally conductive body 21 is of a material that has high thermal conductivity. This can be a metal, such as copper, copper alloy, aluminium, or aluminium alloy, or a ceramic, such as aluminum oxide, aluminum nitride or beryllium oxide. It can also be another material with appropriate thermal conductivity properties.

FIG. 7 shows a view of the cross section A-A, indicated in FIG. 6. The cross section shows the interior of the cooling module 20 and its arrangement with respect to the first and second terminals 11, 12 in the assembled state. The cuboid shape of the cooling module 20 is formed from a box shaped thermally conductive body 21 with which a liquid tight passage 250 is formed from the inlet 251 to the outlet 252. A primary heat receiving surface (first surface) 211 of the thermally conductive body 21 faces and is parallel to a primary heat transmitting surface 111 of the first terminal 11. A primary heat receiving surface (second surface) 221 of the thermally conductive body 21 faces and is parallel to a primary heat transmitting surface 121 of the second terminal 12. A gap between the between the primary heat receiving surface 211 and the primary heat transmitting surface 111 of the first terminal 11 is substantially filled by the thin thermal interface body 260. A gap between the primary heat receiving surface 221 and the primary heat transmitting surface 121 of the second terminal 12 is also substantially filled by the thermal interface body 260.

Inside the cooling module 20, the thermally conductive body 21 has surfaces for transferring heat into the liquid in the passage 250. Specifically, the thermally conductive body 21 has a first convective heat transfer surface 212 facing the passage 250 on an inward side opposite to the primary heat receiving surface 211, and a second convective heat transfer surface 222 facing the passage 250 on an inward side opposite to the primary heat receiving surface 221. In other words, the first and second convective heat transfer surfaces 212, 222 face one another. The cooling module 20 is configured to direct the coolant liquid flowing through the passage 250 past the first and second convective heat transfer surfaces 212, 222 so that heat from the thermally conductive body 21 can be transferred into the coolant liquid. In order to increase flow past the first and second convective heat transfer surfaces 212, 222, a baffle 290 extends inward from between the inlet 251 and the outlet 252.

In this assembled state, when the electrical connector system 1 is in use and heat builds up in the electrical connector 10, the resulting increase in the temperatures of the first and second terminals 11, 12 causes a heat transfer path to develop across the primary heat transmitting surfaces 111, 121, through the thin thermal interface body 260, across the first and primary heat receiving surfaces 211, 221, through the thermally conductive body 21, across the first and second convective heat transfer surfaces 212, 222 and into the coolant liquid, where the heat can be transported away with the discharge of the coolant liquid via the outlet 252.

The electrical connector system 1 is configured to be brought from the disassembled state to the assembled state while the first and second terminals 11, 12 remain fixed to the mounting assembly 13.

Specifically, the electrical connector system 1 is configured to be brought from the disassembled state to the assembled state by inserting the ends of the first and second terminals 11, 12, including the respective connection portions 116, 126, through the base plate 310 and fixing the base plate 310 to the main body 131 with the screws 311. The cooling module 20 can then be inserted between the first and second terminals 11, 12 and fitted to the rear of the base plate 310. The cover plate 320 can then be arranged behind the cooling module 20 and fixed to the base plate 310 by engaging the clips 325 with the hooks 315, thereby fixing the cooling module 20 to the electrical connector 10 in the assembled state.

Alternatively, the cooling module 20 and the fixing means 30 can be combined while the electrical connector system 1 is in the disassembled state. That is, the cooling module 20 can be fit to the rear of the base plate 310, the cover plate 320 can be arranged behind the cooling module 20 and fixed to the base plate 310 by engaging the clips 325 with the hooks 315, and the combined assembly of base plate 310, cooling module 20 and cover plate 320 can be assembled with the electrical connector 10 by inserting the ends of the first and second terminals 11, 12 through the base plate 310 and fixing the base plate 310 to the main body 131 with the screws 311.

The reverse of these processes can be used to bring the electrical connector system 1 from the assembled state to the disassembled state, whereby the cooling module 20 can be separated from the electrical connector 10 to facilitate maintenance, or to reduce weight.

Specifically, the electrical connector system 1 can be brought from the assembled state to the disassembled state by unhooking the clips 325 of the cover plate 320 from the hooks 315 of the base plate 310, separating the cooling module 20 from the base plate 310 and withdrawing the cooling module 20 from between the first and second terminals 11, 12. The screws 311 can then be unscrewed to unfix the base plate 310 from the main body 131, and the base plate 310 can be separated from the electrical connector 10, with the first and second terminals 11, 12 being withdrawn through the base plate 310.

The electrical connector system 1 is also configured to be brought from the assembled state to the disassembled state before the cooling module 20 is separated from the base plate 310. That is, the screws 311 can be unscrewed first to unfix the base plate 310 from the main body 131, and the base plate 310 can then be separated from the electrical connector 10, with the first and second terminals 11, 12 being withdrawn through the base plate 310, while the cooling module 20 remains fixed to the rear of the base plate 310 by the cover plate 320. Then, while the electrical connector system 1 is in the disassembled state, the cooling module 20 can, if necessary, be separated from the fixing means 30 by unclipping the clips 325 of the cover plate 320 from the hooks 315 of the base plate 310, and then separating the cooling module 20 from the base plate 310 and the cover plate 320.

In this embodiment, the base plate 310 and the cover plate 320 are separable from the mounting assembly 10 and the cooling module 20. However, the base plate 310 may be part of the mounting assembly 10. In this case the base plate 310 may be fixed to or integrally formed with the main body 131 or secondary locking body 132. Also, the cover plate 320 may be part of the cooling module 20. In this case the cover plate 320 may be fixed to or integrally formed with the cooling module 20. Also, both the base plate 310 and the cover plate 320 may be part of the cooling module 20. In this case the base plate 310 and the cover plate 320 may each be fixed to or integrally formed with the cooling body. In these cases the alternative ways of bringing the electrical connector system 1 from the disassembled state to the assembled state, and from the assembled state to the disassembled state, are restricted but at least one of the alternatives described above will remain possible.

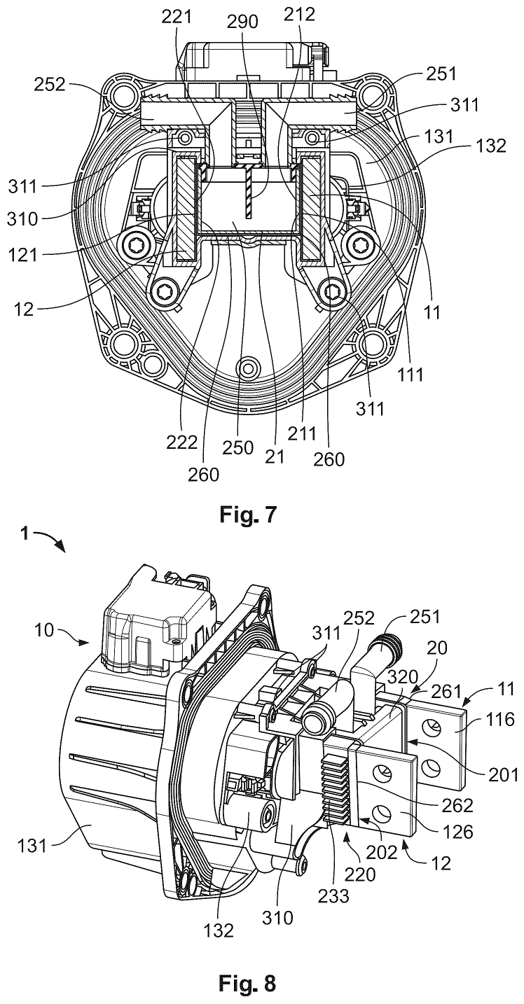

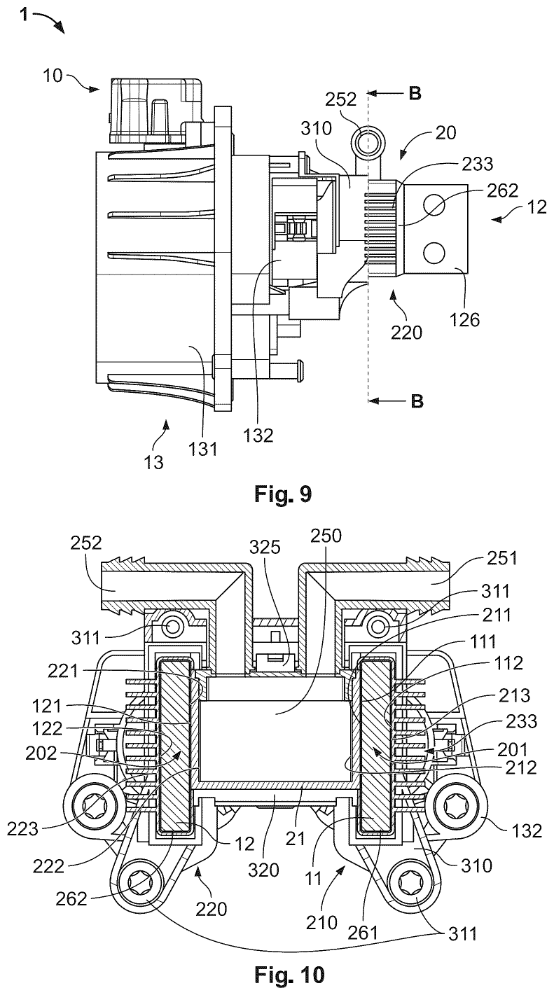

FIGS. 8-10 illustrate the electrical connector system 1 in accordance with an exemplary embodiment. The electrical connector system 1 of the second embodiment is similar to the first embodiment but differs in the configuration of the cooling module 20. Features of the second embodiment that are identical to those of the first embodiment are disclosed in the description of the first embodiment with reference to FIGS. 1 to 7. Features of the second embodiment that differ from those of the first embodiment are described below.

The thermally conductive body 21 differs from that of the first embodiment in that it includes a first air-cooled portion 210 and a second air-cooled portion 220. The first air-cooled portion 210 extends from one side of the cooling module 20 to define a first opening 201. The second air-cooled portion 220 extends from the opposite side to define a second opening 202. The first and second openings 201, 202 are configured to receive, respectively, the first and second terminals 11, 12 when the electrical connector system 1 is in the assembled state, so that portions on the upper, lower and outer surfaces of the first and second terminals 11, 12 can serve as secondary heat transmitting surfaces 112, 122 for transmitting heat to the thermally conductive body 21.

More specifically, an inner surface of the first opening 201 includes the primary heat receiving surface 211 and secondary heat receiving surfaces 213. As in the first embodiment, in the assembled state, the primary heat transmitting surface 111 of the first terminal 11 faces the primary heat receiving surface 211. In addition, the secondary heat transmitting surfaces 112 of the first terminal 11 face heat receiving surfaces 213 of the first air-cooled portion 210.

Similarly, an inner surface of the second opening 202 includes the primary heat receiving surface 221 and secondary heat receiving surfaces 223. The primary heat transmitting surface 121 of the second terminal 12 faces the primary heat receiving surface 221. In addition, the secondary heat transmitting surfaces 122 of the second terminal 12 face heat receiving surfaces 223 of the second air-cooled portion 220.

Instead of the thin thermal interface body 260 that is folded around the outside of the cooling module as in the first embodiment, the second embodiment is instead provided with first and second thin interface bodies 261, 262 that line the inner surfaces of, respectively, the first and second openings 201, 202. In the assembled state, the first thermal interface body substantially fills the gap between the primary heat transmitting surface 111 and the primary heat receiving surface 211, and a gap between the secondary heat transmitting surfaces 112 and the heat receiving surfaces 213 of the first air-cooled portion 210. Similarly, the second thermal interface body substantially fills the gap between the primary heat transmitting surface 121 and the primary heat receiving surface 221, and a gap between the secondary heat transmitting surfaces 122 and the heat receiving surfaces 223 of the second air cooled portion 220.

The first and second air-cooled portions 210, 220 each have a plurality of fins 233 for increasing convective heat transfer to the surrounding air.

In the assembled state, when the electrical connector system 1 is in use and heat builds up in the electrical connector 10 the resulting increase in the temperatures of the first and second terminals 11, 12 causes a heat transfer path to develop in the same way as in the first embodiment, whereby the heat can be transported away with the flow of the coolant liquid, out via the outlet 252. In addition, secondary heat transfer paths develop across the secondary heat transmitting surfaces 112, 122, through the first and second thermal interface bodies 261, 262, across the heat receiving surfaces 213, 223, through the first and second air-cooled portions 210, 220, to the surfaces of the plurality of fins 233, where the heat is transferred to the surrounding air, to be transported away through natural or forced convection.

According to the second embodiment, the heat management capacity can be increased by the increased heat transfer to the surrounding air that is provided by the plurality of the fins 233.

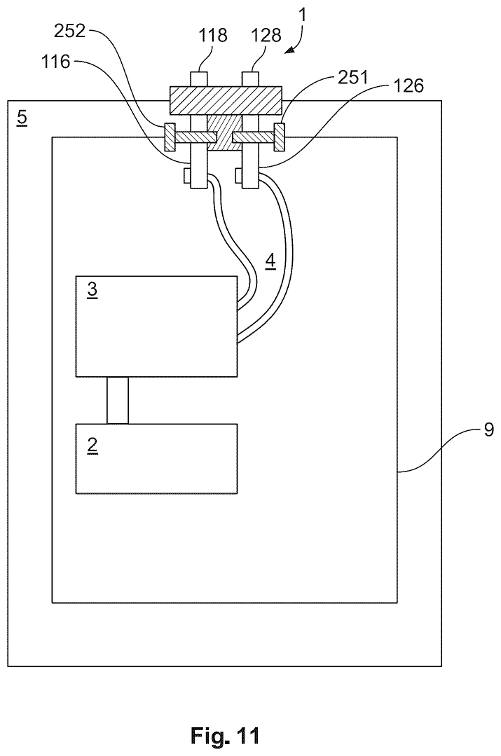

In accordance with an exemplary embodiment, a vehicle 5 is provided which has an electrical connector system 1 according to at least one of the first and second embodiments. As shown in the schematic in FIG. 11, the vehicle 5 uses an electric motor 2 for propulsion. The electric motor 2 is supplied electric power from a battery 3. Cables 4 run from the connection portions 116, 126 of the first and second terminals 11, 12 to the battery 3. The electrical connector 10 is mounted to the vehicle 5 and configured to receive a plug from an external power circuit (not shown), so that contacts in the plug come into contact with the contact portions 118, 128 of the first and second terminals 11, 12. Power can then be supplied from through the plug to the contact portion 118, 128, through the first and second terminals 11, 12 to the connection portions 116, 126, to the cables 4 and hence to the battery 3. The vehicle 5 also has a coolant circuit 9 that circulates coolant liquid through the cooling module 20 by supplying the coolant liquid to the inlet 251 and receiving the coolant liquid from the outlet 252. The coolant circuit 9 may have a radiator or similar means (not shown) for dissipating heat from the coolant liquid to the environment.

In the embodiments described above, the thin thermal interface bodies 260, 261, 262 are of an electrically isolating material so that the one or more thermally conductive bodies 21 can be electrically isolated from the first and second terminals 11, 12. However, the one or more thermally conductive bodies 21 may be electrically connected to one or more of the first and second terminals 11, 12 as long as the first and second terminals 11, 12 remain electrically isolated from one another. For example, a thin thermal interface body 261 that is electrically isolating may be provided for isolating the one or more thermally conductive bodies 21 from the first terminal 11, while the one or more thermally conductive bodies 21 are electrically connected to the second terminal 12. Or, the one or more thermally conductive bodies 21 may include one thermally conductive body 21 that is electrically connected to the first terminal 11 and another thermally conductive body 21 that is electrically connected to the second terminal 12. In this case the two thermally conductive bodies 21, 21 may be electrically isolated from one another by an electrically isolating structure of the cooling module 20. In this case, it is possible to use thin thermal interface bodies that are electrically conductive, or to omit the thin thermal interface bodies. A dielectric coolant liquid may be used to improve electrical isolation between the first and second terminals 11, 12.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112(f), unless and until such claim limitations expressly use the phrase “means for” followed by a statement of function void of further structure.

What is claimed is:

1. An electrical connector system comprising:
an electrical connector that includes a first terminal, a second terminal, and a mounting assembly to which the first and second terminals are fixed;
a cooling module for transferring heat from the electrical connector to a liquid when the electrical connector system is in an assembled state, the cooling module including a passage for conveying the liquid and one or more thermally conductive bodies for conducting heat from the first and second terminals to the passage in the assembled state; and
fixing means for fixing the cooling module to the electrical connector in the assembled state,
wherein, in a disassembled state, the cooling module is physically independent of the electrical connector,
the electrical connector system configured to be brought from the disassembled state to the assembled state while the first and second terminals remain fixed to the mounting assembly, and
the electrical connector system is configured to be brought from the assembled state to the disassembled state while the first and second terminals remain fixed to the mounting assembly.

2. The electrical connector system according to claim 1, wherein
the one or more thermally conductive bodies have one or more convective heat transfer surfaces that define at least a portion of the passage, and
in the assembled state, at least a portion of the one or more convective heat transfer surfaces is interposed between the first and second terminals.

3. The electrical connector system according to claim 1, wherein in the assembled state, a first surface of the one or more thermally conductive bodies is substantially parallel to and facing a primary heat transmitting surface of the first terminal and a second surface of the one or more thermally conductive bodies is substantially parallel to and facing a primary heat transmitting surface of the second terminal.

4. The electrical connector system according to claim 3, wherein the primary heat transmitting surfaces of the first and second terminals are substantially flat.

5. The electrical connector system according to claim 4, wherein the primary heat transmitting surfaces of the first and second terminals face one another and are substantially parallel.

6. The electrical connector system according to claim 5, wherein
each of the first and second terminals has a secondary heat transmitting surface that is parallel to and faces a direction opposite to the respective primary heat transmitting surface,
the one or more thermally conductive bodies include a first air cooled portion with a plurality of fins and a second air cooled portion with a plurality of fins, and
in the assembled state, a surface of the first air-cooled portion is substantially parallel to and facing the secondary heat transmitting surface of the first terminal, and a surface of the second air-cooled portion is substantially parallel to and facing the secondary heat transmitting surface of the second terminal.

7. The electrical connector system according to claim 1, wherein
the mounting assembly comprises a main body and secondary locking body that is fixed to the main body, and
each of the first and second terminals has a protruding portion that is clamped between the main body and the secondary body.

8. The electrical connector system according to claim 1, wherein each of the first and second terminals comprises a connection portion for connection to a cable, and wherein each connection portion has a hole for receiving a bolt of a cable connector.

9. The electrical connector system according to claim 8, wherein the cooling module has a first opening and a second opening and is configured to simultaneously receive the connection portion of the first terminal through the first opening and the connection portion of the second terminal through the second opening when the electrical connector system is brought from the disassembled state to the assembled state.

10. The electrical connector system according claim 1, wherein
the cooling module includes one or more thin thermal interface bodies that are electrically insulative and fixed to at least a portion of the one or more thermally conductive bodies, and
in the assembled state, the one or more thin thermal interface bodies are interposed between the one or more thermally conductive bodies and at least one of the first and second terminals, and contact the at least one of the first and second terminals.

11. The electrical connector system according to claim 9, wherein the one or more thin thermal interface bodies are made of an elastometric material.

12. The electrical connector system according claim 1, wherein
the mounting assembly has one or more threaded holes,
the fixing means includes a base plate that has one or more holes and is configured to fit the cooling module,
the fixing means is configured to be fixed to the mounting assembly in the assembled state by one or more screws, each of the one or more screws penetrating one of the one or more holes and threading into one of the one or more threaded holes.

13. The electrical connector system according to claim 12, wherein the fixing means includes a cover plate and is configured to fix the cooling module in the assembled state with a physical interlock between the base plate and the cover plate, the physical interlock being configured to be released by elastic deformation of the base plate and/or the cover plate.

14. The electrical connector system according to claim 1, wherein the one or more thermally conductive bodies are of a thermally conductive ceramic.

15. A vehicle comprising:
an electrical connector system including an electrical connector that includes a first terminal, a second terminal, and a mounting assembly to which the first and second terminals are fixed, the electrical connector system including a cooling module for transferring heat from the electrical connector to a coolant liquid when the electrical connector system is in an assembled state, the cooling module including a passage for conveying the coolant liquid and one or more thermally conductive bodies for conducting heat from the first and second terminals to the passage in the assembled state, the electrical connector system including fixing means for fixing the cooling module to the electrical connector in the assembled state, wherein, in a disassembled state, the cooling module is physically independent of the electrical connector, wherein the electrical connector system configured to be brought from the disassembled state to the assembled state while the first and second terminals remain fixed to the mounting assembly, and wherein the electrical connector system is configured to be brought from the assembled state to the disassembled state while the first and second terminals remain fixed to the mounting assembly;
an electric motor for propelling the vehicle;
a battery for supplying electric power to the electric motor; and
a coolant circuit configured to circulate the coolant liquid through the passage, wherein
the electrical connector system is in the assembled state, is fixed to the vehicle via the mounting assembly, and is connected to the battery such that electric power applied to the first and second terminals can charge the battery.

16. The vehicle according to claim 15, wherein the one or more thermally conductive bodies have one or more convective heat transfer surfaces that define at least a portion of the passage, and, in the assembled state, at least a portion of the one or more convective heat transfer surfaces is interposed between the first and second terminals.

17. The vehicle according to claim 15, wherein in the assembled state, a first surface of the one or more thermally conductive bodies is substantially parallel to and facing a primary heat transmitting surface of the first terminal and a second surface of the one or more thermally conductive bodies is substantially parallel to and facing a primary heat transmitting surface of the second terminal.

18. The vehicle according to claim 15, wherein the mounting assembly comprises a main body and secondary locking body that is fixed to the main body, and each of the first and second terminals has a protruding portion that is clamped between the main body and the secondary body.

19. The vehicle according to claim 15, wherein each of the first and second terminals comprises a connection portion for connection to a cable, and wherein each connection portion has a hole for receiving a bolt of a cable connector.

20. The vehicle according to claim 15, wherein
the cooling module includes one or more thin thermal interface bodies that are electrically insulative and fixed to at least a portion of the one or more thermally conductive bodies, and
in the assembled state, the one or more thin thermal interface bodies are interposed between the one or more thermally conductive bodies and at least one of the first and second terminals, and contact the at least one of the first and second terminals.
